(19) United States
(12) Patent Application Publication
(10) Pub. No.: US 2025/0140676 A1
(43) Pub. Date: May 1, 2025

(54) WIRING STRUCTURE, METHOD OF MANUFACTURING THE WIRING STRUCTURE, AND SEMICONDUCTOR PACKAGE

(71) Applicant: Samsung Electronics Co., Ltd., Suwon-si (KR)

(72) Inventors: Jeongrim SEO, Suwon-si (KR); Pyunghwa HAN, Suwon-si (KR); JoongSun KIM, Suwon-si (KR)

(73) Assignee: Samsung Electronics Co., Ltd., Suwon-si (KR)

(21) Appl. No.: 18/637,844

(22) Filed: Apr. 17, 2024

(30) Foreign Application Priority Data
Oct. 26, 2023 (KR) 10-2023-0144677

(51) Int. Cl. H01L 23/498; H01L 21/48; H01L 21/56; H01L 23/00; H01L 23/31

(52) U.S. Cl. CPC H01L 23/49838; H01L 21/4857; H01L 21/568; H01L 23/3128; H01L 23/49822; H01L 24/19; H01L 24/20; H01L 2224/19; H01L 2224/211

(57) ABSTRACT

A wiring structure may include a first wiring layer including a first via pad, a first insulating layer covering the first wiring layer, a second wiring layer on the first insulating layer and including a second via pad defining a hole, a second insulating layer on the first insulating layer and covering the second wiring layer, a third wiring layer on the second insulating layer and including a third via pad, and a via integrally penetrating the first insulating layer and the second insulating layer, filling the hole of the second via pad, and connecting the first via pad, the second via pad, and the third via pad to each other, wherein the first insulating layer covers upper and side surfaces of the first via pad, and a diameter of the first via pad is smaller than diameters of the second via pad and the third via pad.

### CROSS-REFERENCE TO RELATED APPLICATION

This application claims priority to and the benefit of Korean Patent Application No. 10-2023-0144677 filed in the Korean Intellectual Property Office on Oct. 26, 2023, the entire contents of which are incorporated herein by reference.

### BACKGROUND

### (a) Field

The present disclosure relates to wiring structures, methods of manufacturing the same, and semiconductor packages including the same.

### (b) Description of the Related Art

In the field of semiconductor package, stack via technology in which vias are formed to overlap each other on a plane is known. Such stack vias may be manufactured by sequentially forming a via penetrating a lower insulating layer and a via penetrating an upper insulating layer that are stacked together. In addition, each via constituting the stack via may be manufactured by forming a via hole in an insulating layer through laser processing and filling the via hole with plating.

At this time, the size of the via is limited to the size of a via hole that can be formed through laser processing, and implementing the via hole with a fine size is limited. In addition, eccentricity may occur due to a misalignment between via holes and via pads, and a via needs to be formed in each layer, which may make a process complicated.

### SUMMARY

Some example embodiments of the present disclosure provide wiring structures capable of implementing a fine pitch and thereby increasing a degree of freedom of wiring, and semiconductor packages to which the wiring structure is applied.

Some example embodiments of the present disclosure provide wiring structures capable of improving an alignment between vias and via pads and semiconductor packages to which the wiring structure is applied.

Some example embodiments of the present disclosure provide wiring structures capable of simplifying a process and semiconductor packages to which the wiring structure is applied.

According to an example embodiment of the present disclosure, a wiring structure may include a first wiring layer including a first via pad, a first insulating layer covering the first wiring layer, a second wiring layer on the first insulating layer, and including a second via pad defining a hole, a second insulating layer on the first insulating layer and covering the second wiring layer, a third wiring layer on the second insulating layer and including a third via pad, and a via integrally penetrating the first insulating layer and the second insulating layer, filling the hole of the second via pad, and connecting the first via pad, the second via pad, and the third via pad to each other, wherein the first insulating layer covers upper and side surfaces of the first via pad, and a diameter of the first via pad is smaller than a diameter of the second via pad and a diameter of the third via pad.

According to another example embodiment of the present disclosure, a semiconductor package may include a first redistribution structure, a support substrate on the first redistribution structure, the support substrate including a first wiring layer including a first via pad and a first insulating layer the support substrate defining a through hole, a semiconductor chip in the through hole, an encapsulant filling the through hole and covering the semiconductor chip and the support substrate, and a second redistribution structure on the encapsulant, wherein the second redistribution structure includes a first redistribution layer on the encapsulant and including a second via pad defining a hole, a second insulating layer on the encapsulant and covering the first redistribution layer, a second redistribution layer on the second insulating layer and including a third via pad, and a via integrally penetrating the encapsulant and the second insulating layer, filling the hole of the second via pad, and connecting the first via pad, the second via pad, and the third via pad to each other, the first insulating layer covers upper and side surfaces of the first via pad, and a diameter of the first via pad is smaller than a diameter of the second via pad and a diameter of the third via pad.

According to another example embodiment of the present disclosure, a method of manufacturing a wiring structure may include forming a first wiring layer including a first via pad, forming a first insulating layer covering the first wiring layer, forming a second wiring layer on the first insulating layer, the second wiring layer including a second via pad, the second via pad defining a hole, forming a second insulating layer covering the second wiring layer on the first insulating layer, forming a via hole integrally penetrating the first insulating layer and the second insulating layer to expose an upper surface of the first via pad, an inner surface of the second via pad surrounding the hole and an upper surface adjacent to the inner surface of the second via pad, forming a via filling the via hole, and forming a third wiring layer including a third via pad connected to the via on the second insulating layer.

### BRIEF DESCRIPTION OF THE DRAWINGS

FIG. 1 is a cross-sectional view of a wiring structure according to an example embodiment of the present disclosure.

FIG. 2 is a top view of a via and a via pad on a first bottom surface of the via of FIG. 1.

FIG. 3 is a top view of a via and a via pad on a second bottom surface of the via of FIG. 1.

FIGS. 4 to 9 are manufacturing process diagrams of the wiring structure of FIG. 1 according to an example embodiment.

FIG. 10 is a modified cross-sectional view of an area A of FIG. 1 according to an example embodiment.

FIG. 11 is a top view of a via and a via pad on a first bottom surface of the via of FIG. 10.

FIG. 12 is a top view of a via and a via pad on a second bottom surface of the via of FIG. 10.

FIG. 13 is a modified cross-sectional view of the area A of FIG. 1 according to an example embodiment.

FIG. 14 is a cross-sectional view of a semiconductor package according to an example embodiment of the present disclosure.

FIG. 15 is a cross-sectional view of a semiconductor package according to an example embodiment of the present disclosure.

FIGS. 16 to 25 are manufacturing process diagrams of a semiconductor package according to an example embodiment of the present disclosure.

### DETAILED DESCRIPTION

Hereinafter, with reference to the accompanying drawings, various example embodiments of the present disclosure will be described in detail so that those skilled in the art may easily carry out the present disclosure. The present disclosure may be embodied in many different forms and is not limited to the example embodiments set forth herein.

In order to clearly explain the present disclosure in the drawings, parts irrelevant to the description are omitted, and the same reference numerals are used for the same or similar elements throughout the specification.

In addition, since the size and thickness of each component shown in the drawings are arbitrarily shown for convenience of description, the present disclosure is not necessarily limited to those shown. In the drawings, the thickness of layers, films, panels, regions, etc., are exaggerated for clarity. In addition, in the drawings, for convenience of explanation, thicknesses of some layers and areas are exaggerated.

In addition, throughout the specification, being “connected” does not only mean that two or more elements are “directly connected”, but may mean that two or more elements are “indirectly connected” through other elements. From a similar perspective, this includes not only being “physically connected,” but also being “electrically connected.”

In addition, unless explicitly described to the contrary, the word “comprise”, and variations such as “comprises” or “comprising”, will be understood to imply the inclusion of stated elements but not the exclusion of any other elements.

In addition, it will be understood that when an element such as a layer, film, region, or substrate is referred to as being “on” another element, it may be directly on the other element or intervening elements may also be present. In contrast, when an element is referred to as being “directly on” another element, there are no intervening elements present. In addition, being “above” or “on” a reference part means being above or below the reference part, and does not necessarily mean being “above” or “on” in the opposite direction of gravity.

In addition, throughout the specification, unless explicitly described to the contrary, the word “comprise”, and variations such as “comprises” or “comprising”, will be understood to imply the inclusion of stated elements but not the exclusion of any other elements.

In addition, throughout the specification, when it is “on a plane” means when a target portion is viewed from above, and when it is “on a cross section” means when a cross section obtained by vertically cutting a target portion is viewed from the side.

In addition, throughout the specification, sequential numbers such as first, second, etc. are used to distinguish an element from other elements that are the same as or similar to the element, and are not necessarily used with the intention of referring to a specific element. Accordingly, a configuration referred to as a first element in a specific part of the specification may be referred to as a second element in other parts of the specification.

In addition, throughout the specification, a singular reference to an element includes a reference to a plurality of these elements, unless specifically stated to the contrary. For example, an “insulating layer” may be used to mean not only one insulating layer but also a plurality of insulating layers, such as two, three or more.

In addition, throughout the specification, references to one surface and the other surface are intended to distinguish different surfaces from each other, and are not necessarily intended to be limited to a specific surface. Accordingly, a surface referred to as one surface in a specific part of the specification may be referred to as the other surface in other parts of the specification.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, wiring structures and semiconductor packages according to some example embodiments of the present disclosure will be described with reference to the drawings.

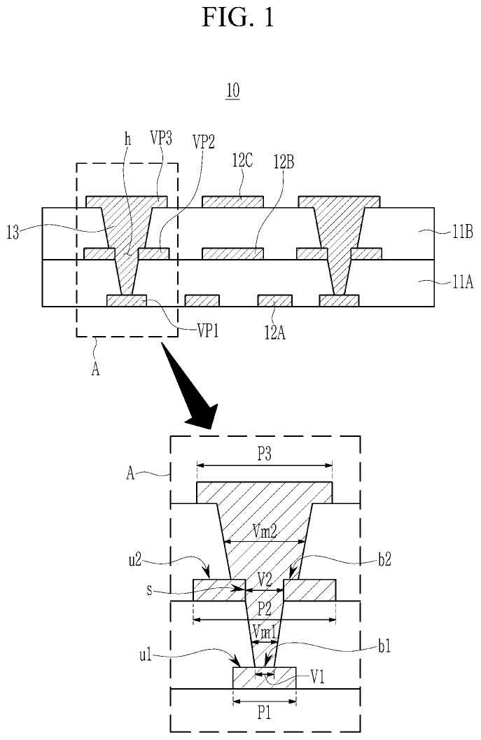

Referring to FIGS. 1 to 3, a wiring structure 10 according to an example embodiment of the present disclosure may include a first wiring layer 12A, a first insulating layer 11A covering the first wiring layer 12A, a second wiring layer 12B disposed on the first insulating layer 11A, a second insulating layer 11B disposed on the first insulating layer 11A and covering the second wiring layer 12B, a third wiring layer 12C disposed on the second insulating layer 11B, and a via 13.

Wiring layers and insulating layers may be formed alternately, the first insulating layer 11A may cover upper and side surfaces of the first wiring layer 12A, and the second insulating layer 11B may cover upper and side surfaces of the second wiring layer 12B.

An insulating material may be used as a material of each of the first insulating layer 11A and the second insulating layer 11B, and may use, for example, thermosetting resin such as epoxy resin, thermoplastic resin such as polyimide, prepreg, Ajinomoto Build-up Film (ABF), etc.

A thickness of each of the first insulating layer 11A and the second insulating layer 11B is not particularly limited and may vary depending on the design. The thicknesses of the first insulating layer 11A and the second insulating layer 11B may be the same as or different from each other.

The first wiring layer 12A, the second wiring layer 12B, and the third wiring layer 12C may respectively include a first via pad VP1, a second via pad VP2, and a third via pad VP3 for connection to the via 13. The first via pad VP1 and the second via pad VP2 may also be covered with the first insulating layer 11A and the second insulating layer 11B, respectively.

The first via pad VP1 may be disposed on a lower side of the via 13, so that an upper surface u1 of the first via pad VP1 is in contact with the via 13.

The second via pad VP2 may have a hole h, and the hole h may be filled with the via 13.

The third via pad VP3 may be disposed on the via 13, so that a lower surface of the third via pad VP3 is in contact with the via 13. The third via pad VP3 and the via 13 may be integrally formed through the same process, and may be integrated without boundaries.

Each of the first wiring layer 12A, the second wiring layer 12B, and the third wiring layer 12C may further include wiring patterns for providing, for example, signal, power, and ground in addition to a via pad. The wiring pattern may be connected to the via pad, and the wiring pattern and the via pad connected thereto may not have a boundary with each other.

A conductive material may be used as a material of each of the first wiring layer 12A, the second wiring layer 12B, and the third wiring layer 12C, and may use, for example, aluminum (AI), copper (Cu), gold (Au), silver (Ag), platinum (Pt), tin (Sn), chromium (Cr), palladium (Pd), lead (Pb), titanium (Ti), or an alloy thereof, but example embodiments are not limited thereto.

The via 13 may integrally penetrate the first insulating layer 11A and the second insulating layer 11B, fill the hole h of the second via pad VP2, and connect the first via pad VP1, the second via pad VP2, and the third via pad VP3 to each other. The via 13 may be in physical contact with and electrically connect the first via pad VP1, the second via pad VP2, and the third via pad VP3 to each other.

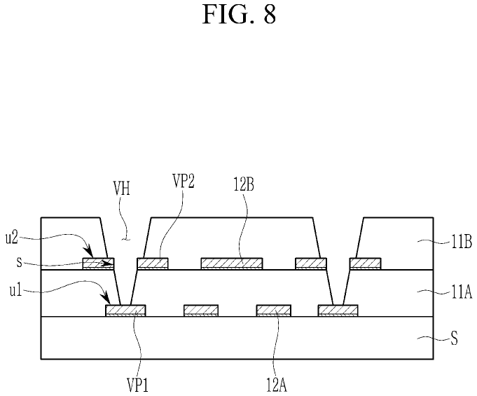

As will be described below, the via 13 may be formed by forming the first wiring layer 12A, the first insulating layer 11A, the second wiring layer 12B, and the second insulating layer 11B, forming a via hole VH (see FIG. 8) integrally penetrating the first insulating layer 11A and the second insulating layer 11B through laser processing, and then filling the via hole VH with a conductive material. At this time, the second via pad VP2 of the second wiring layer 12B may be formed to have the hole h, and the second via pad VP2 may be disposed in an area around the hole h such that a processing area of the via hole VH formed in the first insulating layer 11A is limited. Accordingly, a diameter of the hole h included in the second via pad VP2 may be adjusted such that a diameter of the via 13 in the area penetrating the first insulating layer 11A may be adjusted.

The via 13 may cover an inner surface s of the second via pad VP2 and an upper surface u2 adjacent to the inner surface s of the second via pad VP2. The inner surface s of the second via pad VP2 refers to a surface surrounding the hole h of the second via pad VP2. When the via hole VH is formed, the second insulating layer 11B may be removed such that the inner surface s and the upper surface u2 of the second via pad VP2 may be exposed, and then a conductive material may be filled in an exposed area of the second via pad VP2 such that the via 13 may cover the inner surface s and the upper surface u2 of the second via pad VP2.

In addition, the via 13 may cover the upper surface u1 of the first via pad VP1. When the via hole VH is formed, the first via pad VP1 may serve as a processing stop layer, and a conductive material may be filled at the upper surface u1 of the first via pad VP1 exposed by removing first insulating layer 11A such that the via 13 may cover the upper surface u1 of the first via pad VP1.

In the specification, a surface of the via 13 in contact with the upper surface u1 of the first via pad VP1 is referred to as a first bottom surface b1, and a surface in contact with the upper surface u2 of the second via pad VP2 is referred to as a second bottom surface b2.

In the area penetrating the first insulating layer 11A and the area penetrating the second insulating layer 11B, the via 13 may have a tapered shape, a cylindrical shape, etc. in which a width of the via hole VH is constantly or rapidly narrowed in a direction from the second insulating layer 11B toward the first insulating layer 11A according to a processed shape of the via hole VH.

The via 13 may be directly formed on the via hole VH, and the via 13 may be in contact with a processed configuration and an exposed configuration (e.g., a boundary of the via hole VH defined by the first insulating layer 11A, the second insulating layer 11B, the first via pad VP1 and the second via pad VP2) when the via hole VH is formed. Accordingly, in each of the areas penetrating the first insulating layer 11A and the second insulating layer 11B, the via 13 may be in contact with a corresponding one of the first insulating layer 11A and the second insulating layer 11B. In addition, the via 13 may be in contact with each of the upper surface u1 of the first via pad VP1, the inner surface s and the upper surface u2 adjacent to the inner surface s of the second via pad VP2.

A diameter of the via 13 in the area penetrating the second insulating layer 11B is not particularly limited and may correspond to a diameter of the via hole VH that can be formed through laser processing. For example, the diameter of the via 13 in the area penetrating the second insulating layer 11B may be about 100 μm or more.

At a level where the second via pad VP2 is located, because the via hole VH is processed along the hole h of the second via pad VP2, a diameter V2 of the via 13 in an area filling the hole h of the second via pad VP2 may be the same as a diameter of the hole h of the second via pad VP2. Accordingly, the diameter of the hole h of the second via pad VP2 may be adjusted such that the diameter V2 of the via 13 in the area filling the hole h of the second via pad VP2 may be controlled. When the diameter of the hole h of the second via pad VP2 is finely formed through a photolithography process, etc., the diameter V2 of the via 13 in the area filling the hole h of the second via pad VP2 may also be finely formed. For example, the diameter V2 of the via 13 in the area filling the hole h of the second via pad VP2 may be about 45 μm to about 55 μm.

At this time, the diameter V2 of the via 13 in the area filling the hole h of the second via pad VP2 may be constant.

This is because the hole h of the second via pad VP2 may be formed to have a constant diameter through the photolithography process, and the second via pad VP2 may not be processed with a laser when the via hole VH is formed.

An average diameter Vm1 of the vias 13 in the area penetrating the first insulating layer 11A may be smaller than an average diameter Vm2 of the vias 13 in the area penetrating the second insulating layer 11B. This is because the second via pad VP2 is disposed in the area around the hole h of the second via pad VP2 such that the processing area of the via hole VH formed in the first insulating layer 11A is limited. When the via 13 has the tapered shape in the area penetrating the first insulating layer 11A and the area penetrating the second insulating layer 11B, the diameter of the via 13 may not be constant, and thus, in this paragraph, the term average diameter has been used.

From a similar perspective, the diameter of the via 13 throughout the area penetrating the first insulating layer 11A may be the same as or smaller than the diameter V2 of the via 13 in the area filling the hole h of the second via pad VP2.

The diameter V1 of the via 13 at the upper surface u1 of the first via pad VP1 may also be adjusted according to the diameter of the hole h of the second via pad VP2. When the diameter of the hole h of the second via pad VP2 is finely formed, the diameter V1 of the via 13 on the upper surface u1 of the first via pad VP1 may also be finely formed. For example, the diameter V1 of the via 13 on the upper surface u1 of the first via pad VP1 may be about 40 μm to about 50 μm.

A diameter P1 of the first via pad VP1 may be smaller than a diameter P2 of the second via pad VP2 and a diameter P3 of the third via pad VP3. The diameter V1 of the via 13 on the upper surface u1 of the first via pad VP1 may be finely formed, and thus, the first via pad VP1 for connection to the via 13 may have a fine diameter. The first via pad VP1 may be finely formed through the photolithography process. For example, the diameter P1 of the first via pad VP1 may be about 65 μm to about 75μm. Accordingly, the first via pad VP1 may be located within an area of each of the second via pad VP2 and the third via pad VP3 on a plane, and may overlap each of the second via pad VP2 and the third via pad VP3.

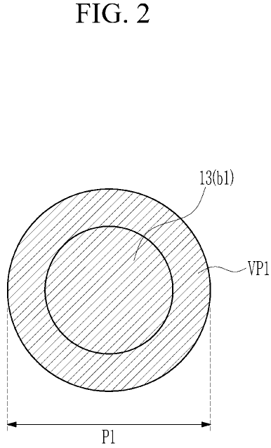

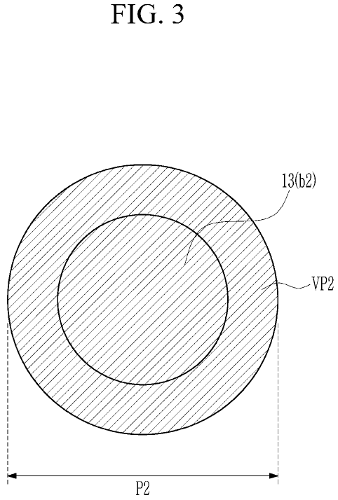

Referring to FIGS. 2 and 3, each of the via 13, the first via pad VP1, and the second via pad VP2 may have a circular shape on the plane. The via 13 may overlap each of the first via pad VP1 and the second via pad VP2 on the plane. For stable connection to the via 13, the diameter P1 of the first via pad VP1 may be larger than the diameter of the via 13 at the first bottom surface b1, and the diameter P2 of the second via pad VP2 may be larger than the diameter of the via 13 at the second bottom surface b2.

According to some example embodiments of the present disclosure, the diameter of the via 13 may be adjusted in the area penetrating the first insulating layer 11A through the second via pad VP2 having the hole h, and accordingly, the first via pad VP1 may also have a fine diameter. Through this, the wiring structure capable of implementing a fine pitch and thereby increasing a degree of freedom of wiring may be provided. In addition, the vias 13 may be formed at once to integrally penetrate the first insulating layer 11A and the second insulating layer 11B, and thus, the wiring structure capable of simplifying the process may be provided.

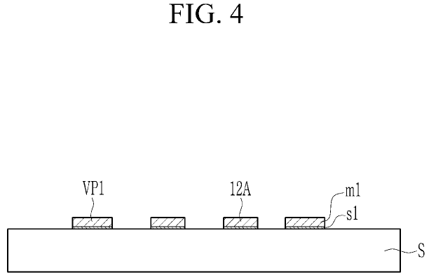

FIGS. 4 to 9 are manufacturing process diagrams of the wiring structure of FIG. 1 according to an example embodiment.

A method of manufacturing the wiring structure according to an embodiment of the present disclosure may include forming the first wiring layer 12A including the first via pad VP1, forming the first insulating layer 11A covering the first wiring layer 12A, forming the second wiring layer 12B including the second via pad VP2 having the hole h on the first insulating layer 11A, forming the second insulating layer 11B covering the second wiring layer 12B on the first insulating layer 11A, forming the via hole VH that integrally penetrates the first insulating layer 11A and the second insulating layer 11B and exposes the upper surface u1 of the first via pad VP1, the inner surface s and the upper surface u2 adjacent to the inner surface s of the second via pad VP2, forming the via 13 that fills the via hole VH, and forming the third wiring layer 12C including the third via pad VP3 connected to the via 13 on the second insulating layer 11B.

Referring to FIG. 4, first, the first wiring layer 12A may be formed on a substrate S. The substrate S may be a temporary support member, substrate, insulating layer, etc. that is removed in a later process. The first wiring layer 12A may be formed by forming, for example, a first seed layer s1 on the substrate S by electroless plating, etc., and forming a first metal layer m1 on the first seed layer s1 by electrolytic plating, etc.

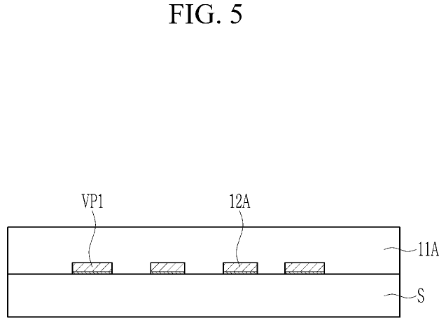

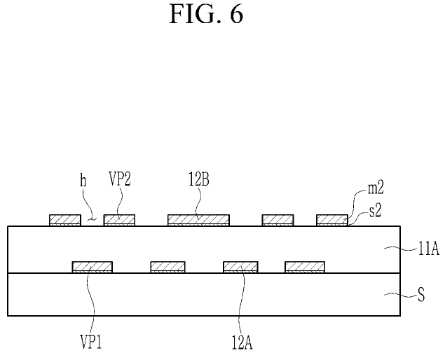

Next, referring to FIGS. 5 and 6, the first insulating layer 11A and the second wiring layer 12B may be formed on the substrate S. Like the first wiring layer 12A, the second wiring layer 12B may be formed by forming a second seed layer s2 on the first insulating layer 11A by electroless plating, etc., and forming a second metal layer m2 on the second seed layer s2 through electrolytic plating, etc. When the second wiring layer 12B is formed, the second via pad VP2 may be patterned to have the hole h in an area where the via 13 is to be formed.

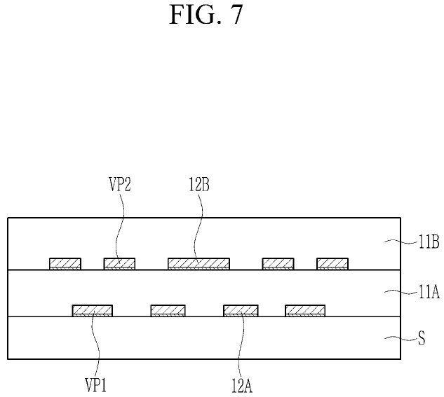

Next, referring to FIGS. 7 and 8, the second insulating layer 11B may be formed on the first insulating layer 11A, and the via hole VH that integrally penetrates first insulating layer 11A and the second insulating layer 11B may be formed. The via hole VH may be formed through laser processing, etc., and the upper surface u1 of the first via pad VP1 and the upper surface u2 of the second via pad VP2 may serve as processing stop layers in areas where first via pad VP1 and the second via pad VP2 are located. Accordingly, the upper surface u1 of the first via pad VP1, the inner surface s and the upper surface u2 adjacent to the inner surface s of the second via pad VP2 may be exposed through the via hole VH.

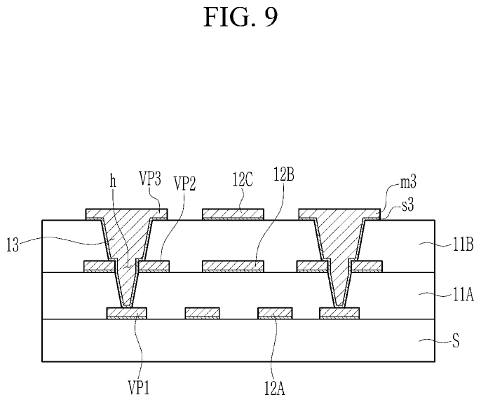

Finally, referring to FIG. 9, the via 13 and the third wiring layer 12C may be formed. The via 13 may be formed by forming a third seed layer s3 on wall and bottom surfaces of the via hole VH by electroless plating, etc., and forming a third metal layer m3 on the third seed layer s3 by electrolytic plating, etc. At this time, the third seed layer s3 and the third metal layer m3 may be formed to extend onto the second insulating layer 11B, and therefore, the third wiring layer 12C may be formed integrally with the via 13.

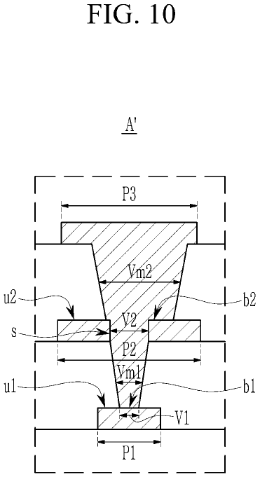

FIG. 10 is a modified cross-sectional view of an area A of FIG. 1.

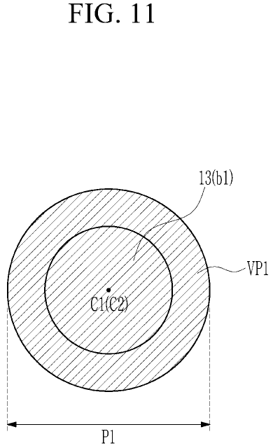

FIG. 11 is a top view of a via and a via pad on a first bottom surface of the via of FIG. 10.

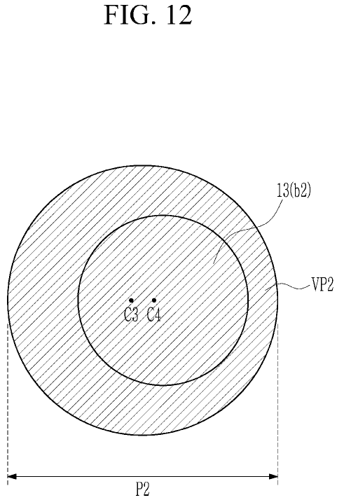

FIG. 12 is a top view of a via and a via pad on a second bottom surface of the via of FIG. 10.

Referring to the drawing, in an area penetrating the second insulating layer 11B, the via 13 may be formed to be biased to one side. When a substrate for via hole processing is aligned, the via hole VH may be processed in a misalignment and deviate with a design area, and thus, eccentricity between the via pad and the via may occur.

According to some example embodiments of the present disclosure, even if eccentricity occurs between the via 13 and the second via pad VP2 in the area penetrating the second insulating layer 11B, because the via hole VH in an area penetrating the first insulating layer 11A is processed through the hole h of the first via pad VP1, the via 13 may be processed along the design area in the area penetrating the first insulating layer 11A, and eccentricity may be mitigated or prevented from occurring between the via 13 and the first via pad VP1.

Accordingly, a distance between a center C2 of the via 13 on the first bottom surface b1 and a center C1 of the first via pad VP1 may be closer than a distance between a center C4 of the via 13 on the second bottom surface b2 and a center C3 of the second via pad VP2. In an ideal case, the center C2 of the via 13 and the center C1 of the first via pad VP1 on the first bottom surface b1 may coincide with each other, and the distance therebetween may be 0.

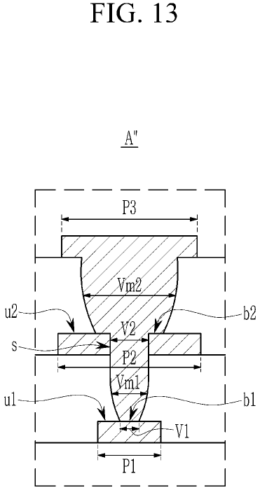

FIG. 13 is a modified cross-sectional view of the area A of FIG. 1 according to an example embodiment.

Referring to the drawing, a diameter of the via 13 in an area penetrating the first insulating layer 11A and an area penetrating the second insulating layer 11B may decrease in a direction (downward direction) from the second insulating layer 11B toward the first insulating layer 11A, and may gradually decrease at a greater ratio as getting closer toward the first insulating layer 11A from the second insulating layer 11B. Therefore, a difference between the diameter of the via 13 at a first point and the diameter of the via 13 at a second point in the downward direction by a specific distance from the first point may be greater than a difference between the diameter of the via 13 at the second point and the diameter of the via 13 at a third point in the downward direction by a specific distance from the second point.

In addition, a side surface of the via 13 in the area penetrating the first insulating layer 11A and the area penetrating the second insulating layer 11B may be a curve on a cross section, and a tangential slope of the curve may decrease in a direction from the second insulating layer 11B toward the first insulating layer 11A.

When an organic insulating material is used as each of the first insulating layer 11A and the second insulating layer 11B, during laser processing, the via hole VH may be formed to gradually decrease at a greater ratio as getting closer toward the first insulating layer 11A from the second insulating layer 11B, and the via 13 formed by filling the via hole VH with a conductive material may have the structure shown in FIG. 13.

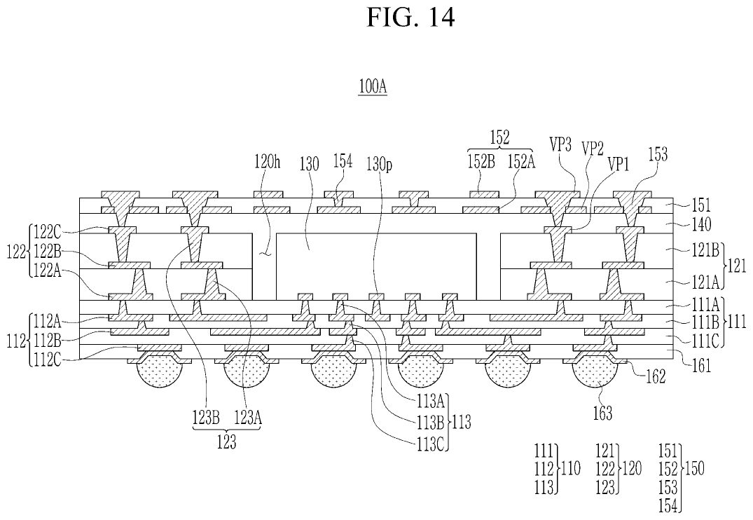

FIG. 14 is a cross-sectional view of a semiconductor package according to an example embodiment of the present disclosure.

Referring to the drawing, a semiconductor package 100A according to an example embodiment of the present disclosure may include a first redistribution structure 110, a support substrate 120 disposed on the first redistribution structure 110 and having a through hole 120h, a semiconductor chip 130 disposed in the through hole 120h, an encapsulant 140 that fills the through hole 120h and covers the semiconductor chip 130 and the support substrate 120, and a second redistribution structure 150 disposed on the encapsulant 140.

The first redistribution structure 110 may include an insulating layer 111, a redistribution layer 112, and a via 113. For example, the first redistribution structure 110 may include a first insulating layer 111A, a first redistribution layer 112A disposed on the first insulating layer 111A, a first via 113A penetrating the first insulating layer 111A and connecting the first redistribution layer 112A to the first wiring layer 122A of the support substrate 120 and a connection pad 130P of the semiconductor chip 130, a second insulating layer 111B disposed on the first insulating layer 111A and covering the first redistribution layer 112A, a second redistribution layer 112B disposed on the second insulating layer 111B, a second via 113B penetrating the second insulating layer 111B and connecting the second redistribution layer 112B to the first redistribution layer 112A, a third insulating layer 111C disposed on the second insulating layer 111B and covering the second redistribution layer 112B, and a third via 113C penetrating the third redistribution layer 112C and connecting the third redistribution layer 112C to the second redistribution layer 112B.

The support substrate 120 may have the through hole 120h and may include an insulating layer 121, a wiring layer 122, and a via 123. For example, the support substrate 120 may include a first wiring layer 122A, a first insulating layer 121A covering the first wiring layer 122A, a second wiring layer 122B disposed on the first insulating layer 121A, a first via 123A penetrating the first insulating layer 121A and connecting the first wiring layer 122A to the second wiring layer 122B, a second insulating layer 121B disposed on the first insulating layer 121A and covering the second wiring layer 122B, and a second via 123B penetrating the third wiring layer 122C and the second insulating layer 121B disposed on the second insulating layer 121B and connecting the third wiring layer 122C to the second wiring layer 122B.

The support substrate 120 may have an embedded trace substrate (ETS) structure, and therefore, the first wiring layer 122A may be buried in the first insulating layer 121A. When the support substrate 110 has the ETS structure, a fine circuit may be implemented, thereby reducing the number of wiring layers and finely controlling a circuit line width. In an example embodiment, the first via 123A may have a tapered shape in a direction from the first wiring layer 122A toward the second wiring layer 122B. In addition, the first via 123A may be integrated with the first wiring layer 122A.

The semiconductor chip 130 may have the connection pad 130P, and may be disposed to face down such that a surface on which the connection pad 130P of the semiconductor chip 130 is disposed faces the first redistribution structure 110. The semiconductor chip 130 may be packaged through a chip first method, and the connection pad 130P may be in contact with the first via 113A of the first redistribution structure 110 and connected to the first redistribution layer 112A.

The encapsulant 140 may be formed of a thermosetting resin such as epoxy molding compound (EMC) or epoxy resin, but example embodiments are not limited thereto.

Like the first redistribution structure 110, the second redistribution structure 150 may include an insulating layer 151, a redistribution layer 152, and vias 153 and 154. For example, the second redistribution structure 150 may include a first redistribution layer 152A disposed on the encapsulant 140, an insulating layer 151 disposed on the encapsulant 140 and covering the first redistribution layer 152A, a second redistribution layer 152B disposed on the insulating layer 151, a first via 153 integrally penetrating the encapsulant 140 and the insulating layer 151 and connecting the second redistribution layer 152B to the third wiring layer 122C of the support substrate 120, and a second via 154 penetrating the insulating layer 151 and connecting the second redistribution layer 152B to the first redistribution layer 152A. However, the number of insulating layers 151 and redistribution layers 152 of the second redistribution structure 150 is not limited to the number shown in FIG. 14. For example, the second redistribution structure 150 may include a greater number of insulating layers 151 and redistribution layers 152 than the number of insulating layers 151 and redistribution layers 152 shown in FIG. 14.

The semiconductor package 100A may further include a protective layer 161, an under bump metal 162, and a conductive bump 163.

The protective layer 161 may be disposed on the first redistribution structure 110 to protect the first redistribution structure 110 from physical, chemical, and mechanical damage. The protective layer 161 may have an opening for connection to the under bump metal 162 and the third redistribution layer 112C.

An insulating material may be used as a material of the protective layer 161, and, for example, an Ajinomoto build-up film (ABF) may be used. However, the material of the protective layer 161 is not limited thereto, and may use a thermosetting resin such as epoxy resin, a thermoplastic resin such as polyimide, or prepreg. In some example embodiments, a solder resist (SR) may be used as the material of the protective layer 161.

The under bump metal 162 may increase connection reliability between the first redistribution structure 110 and the conductive bump 163. The under bump metal 162 may be disposed on the protective layer 161 and may be physically and electrically connected to the third redistribution layer 112C through an opening of the protective layer 161. The under bump metal 162 may include at least one metal layer.

The conductive bump 163 may physically and electrically connect the semiconductor package 100A to other configurations such as a main board, etc. The conductive bump 163 may be, for example, a solder ball.

Meanwhile, the wiring structure 10 according to some example embodiments of the present disclosure may be applied to the semiconductor package 100A. For example, as shown in FIG. 14, the first via 153 connecting the second redistribution layer 152B of the second redistribution structure 150 to the third wiring layer 122C of the support substrate 120 may have a structure of the via 13 of the wiring structure 10 according to one of the above example embodiments of the present disclosure. In addition, the third wiring layer 122C of the support substrate 120, the first redistribution layer 152A and the second redistribution layer 152B of the second redistribution structure 150 may respectively include the first via pad VP1, the second via pad VP2, and the third via pad VP3 of the wiring structure 10 according to one of the above example embodiments of the present disclosure.

However, the area to which the wiring structure 10 according to an example embodiment of the present disclosure is applied is not limited to the area including the first via 153 illustrated in FIG. 14. If desired, the wiring structure 10 according to one of the above example embodiments of the present disclosure may be applied to the first redistribution structure 110 or the support substrate 120. For example, the first redistribution layer 112A, the second redistribution layer 112B, and the third redistribution layer 112C of the first redistribution structure 110 may include the first via pad VP1, the second via pad VP2, and the third via pad VP3, respectively, which may be connected to each other through the via 13 according to one of the above example embodiments of the present disclosure. As another example, the first wiring layer 122A, the second wiring layer 122B, and the third wiring layer 122C of the support substrate 120 may include the first via pad VP1, the second via pad VP2, and the third via pad VP3, respectively, which may be connected to each other through the via 13 according to one of the above example embodiments of the present disclosure.

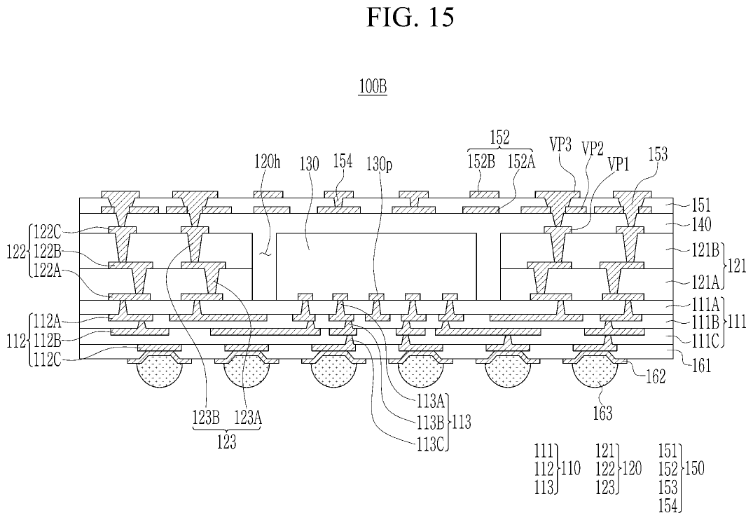

FIG. 15 is a cross-sectional view of a semiconductor package according to an example embodiment of the present disclosure.

Referring to FIG. 15, in a semiconductor package 100B, the first via 123A of the support substrate 120 may have a tapered shape in a direction from the second wiring layer 122B toward the first wiring layer 122A. In addition, the first via 123A may be integrated with the second wiring layer 122B.

The descriptions of other configurations are the same as those specifically described in the description of the semiconductor package 100A in FIG. 14, and thus, detailed descriptions of these configurations are omitted.

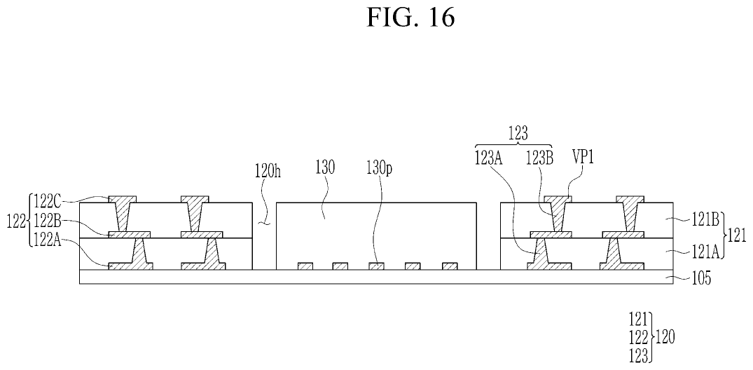

FIGS. 16 to 25 are manufacturing process diagrams of a semiconductor package according to an example embodiment of the present disclosure.

Referring to FIG. 16, first, the support substrate 120 having the through hole 120h is disposed on an adhesive film 105, and the semiconductor chip 130 is disposed in the through hole 120h. The adhesive film 10 may use, for example, an adhesive tape whose adhesive strength is weakened by heat treatment or ultraviolet irradiation, etc. The semiconductor chip 130 may be disposed to face down such that the connection pad 130P faces the adhesive film 10.

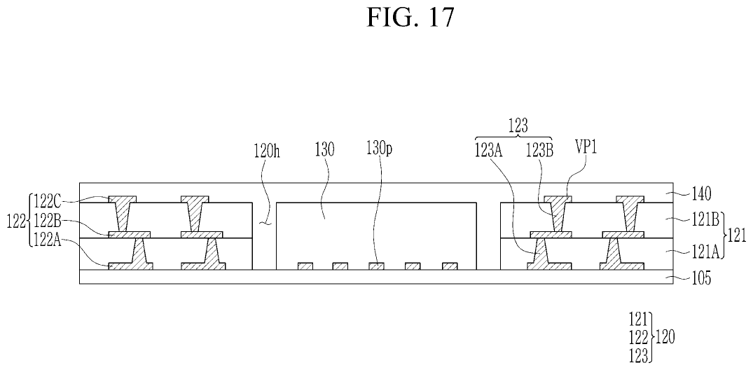

Next, referring to FIG. 17, the semiconductor chip 130 is sealed with the encapsulant 140. A process of sealing the semiconductor chip 130 with the encapsulant 140 may be performed by compression molding, transfer molding, etc.

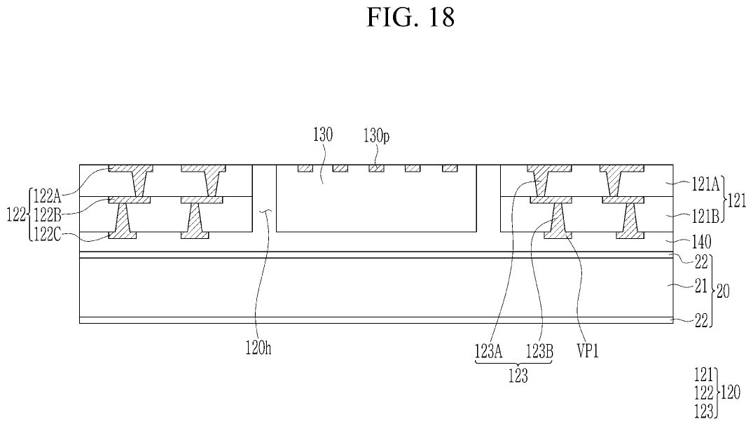

Next, referring to FIG. 18, the first carrier film 20 is attached on the encapsulant 140, and the adhesive film 105 is removed. The first carrier film 20 may be, for example, a copper foil laminate such as a Die Carrier Film (DCF) including the insulating layer 21 and the metal layer 22 disposed on at least one surface of the insulating layer 21. The adhesive film 105 may be removed by heat treatment or ultraviolet irradiation, etc.

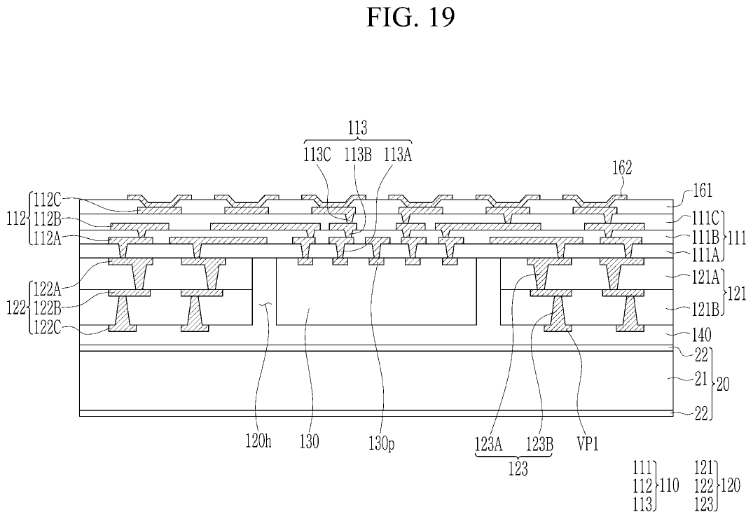

Next, referring to FIG. 19, the first redistribution structure 110 is formed by repeatedly forming the insulating layer 111, the redistribution layer 112, and the via 113 on the semiconductor chip 130 and the support substrate 120. The insulating layer 111, the redistribution layer 112, and the via 113 may be formed, for example, by coating a photosensitive insulating material, forming a via hole VH through an exposure and development process, and then forming the redistribution layer 112 and the via 113.

In addition, the protective layer 161 is formed by laminating an insulating material on the first redistribution structure 110, an opening is formed in the protective layer 161 to expose the third redistribution layer 112C, and then, the under bump metal 162 electrically connected to the redistribution layer 112 is formed on the protection layer 161.

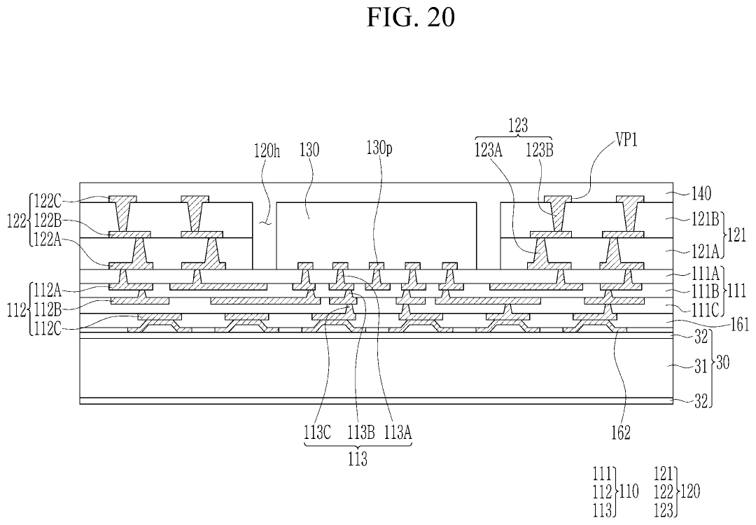

Next, referring to FIG. 20, the first carrier film 20 is removed, and the second carrier film 30 is attached on the under bump metal 162. Like the first carrier film 20, the second carrier film 30 may be a copper foil laminate such as the DCF including the insulating layer 31 and the metal layer 32 disposed on at least one surface of the insulating layer 31.

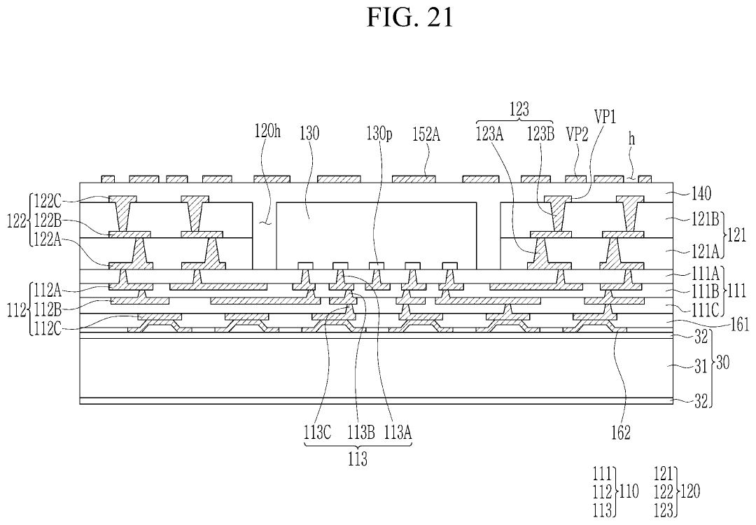

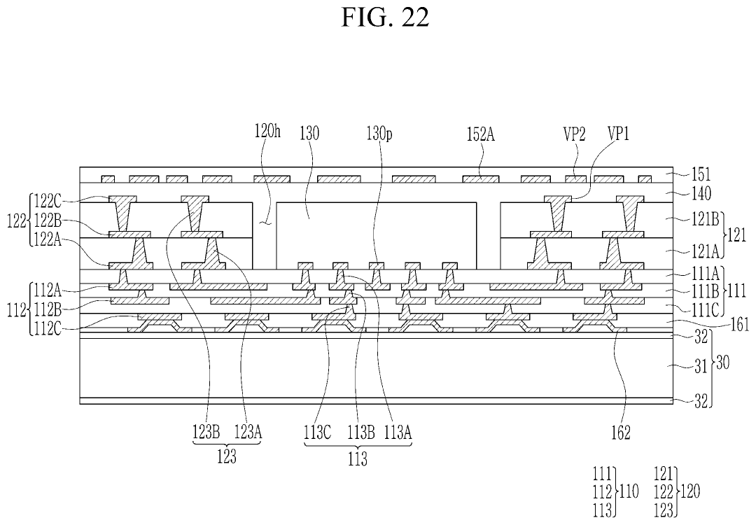

Next, referring to FIGS. 21 and 22, the first redistribution layer 152A including the second via pad VP2 having the hole h is formed on the encapsulant 140, and the insulating layer 151 covering the first redistribution layer 152A is formed on the encapsulant 140. The insulating layer 151 may fill the hole h of the second via pad VP2.

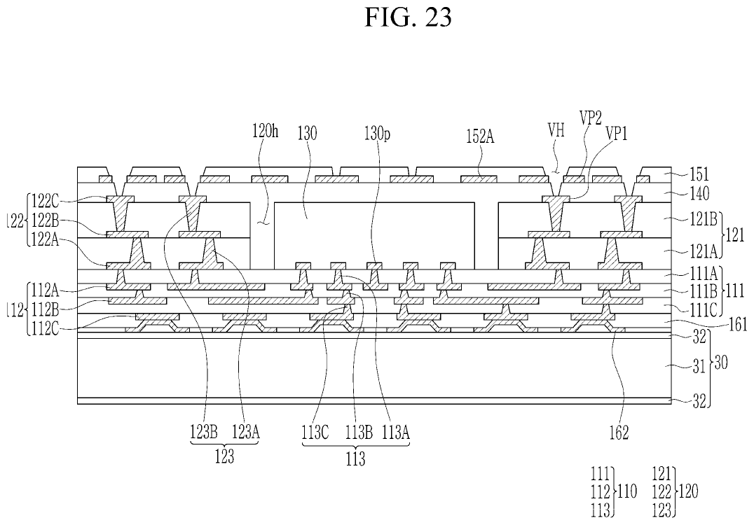

Next, referring to FIG. 23, the via hole VH that integrally penetrates the encapsulant 140 and the insulating layer 151 and exposes an upper surface of the first via pad VP1, an inner surface and an upper surface adjacent to the inner surface of the second via pad VP2 is formed. The via hole VH may be formed through laser processing. At this time, to form the second via 154, a via hole VH that penetrates the insulating layer 151 and exposes the upper surface of the second via pad VP2 may be formed together.

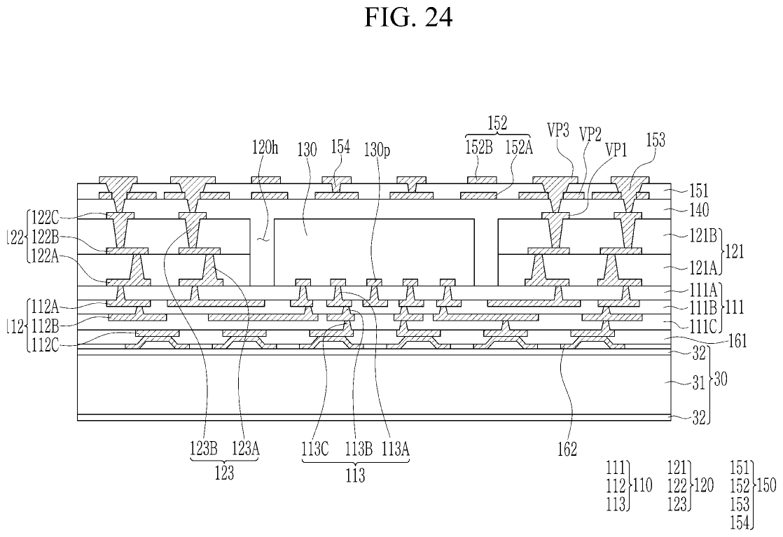

Next, referring to FIG. 24, the second redistribution layer 152B including the first via 153 filling the via hole VH and the third via pad VP3 is formed. The first via 153 and the third via pad VP3 may be integrally formed. At this time, the second via 154 may also be formed together with the first via 153.

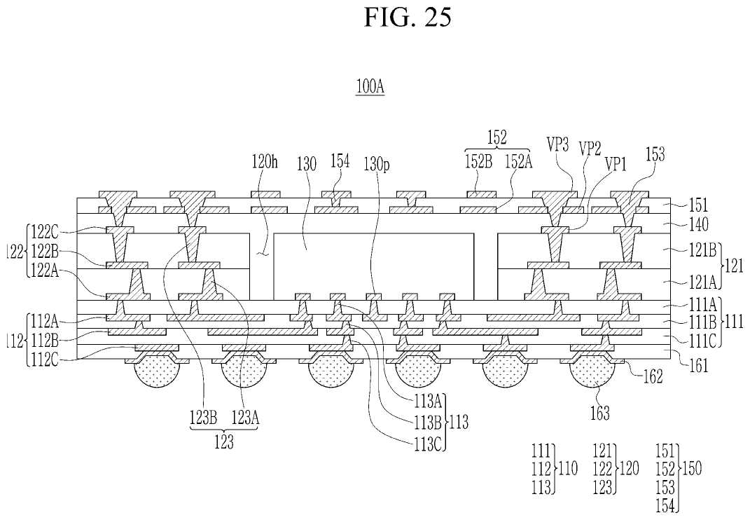

Finally, referring to FIG. 25, the second carrier film 30 is removed and the conductive bump 163 is formed on the under bump metal 162, and thus, the semiconductor package 100A according to an example embodiment of the present disclosure may be manufactured.

Although some example embodiments of the present disclosure have been described in detail above, the scope of the present disclosure is not limited thereto, and various modifications and improvements made by those of ordinary skill in the field to which the present disclosure pertains also belong to the scope of the present disclosure.

What is claimed is:

1. A wiring structure comprising:
a first wiring layer comprising a first via pad;
a first insulating layer covering the first wiring layer;
a second wiring layer on the first insulating layer and comprising a second via pad defining a hole;
a second insulating layer on the first insulating layer and covering the second wiring layer;
a third wiring layer on the second insulating layer and comprising a third via pad; and
a via integrally penetrating the first insulating layer and the second insulating layer, filling the hole of the second via pad, and connecting the first via pad, the second via pad, and the third via pad to each other,
wherein the first insulating layer covers upper and side surfaces of the first via pad, and
a diameter of the first via pad is smaller than a diameter of the second via pad and a diameter of the third via pad.

2. The wiring structure of claim 1, wherein:
the diameter of the first via pad ranges from 65 μm to 75 μm.

3. The wiring structure of claim 1, wherein:
an average diameter of the via in an area penetrating the first insulating layer is smaller than an average diameter of the via in an area penetrating the second insulating layer.

4. The wiring structure of claim 1, wherein:
a diameter of the via ranges from 40 μm to 50 μm at the upper surface of the first via pad.

5. The wiring structure of claim 1, wherein:
a diameter of the via ranges from 45 μm to 55 μm in an area filling the hole of the second via pad.

6. The wiring structure of claim 1, wherein:
a diameter of the via is constant in an area filling the hole of the second via pad.

7. The wiring structure of claim 1, wherein:
when a surface of the via in contact with the upper surface of the first via pad is referred to as a first bottom surface, and a surface of the via in contact with an upper surface of the second via pad is referred to as a second bottom surface,
a distance between a center of the via and a center of the first via pad at the first bottom surface is closer than a distance between the center of the via and a center of the second via pad at the second bottom surface, when viewed in a top view.

8. The wiring structure of claim 1, wherein:
in an area penetrating the first insulating layer and an area penetrating the second insulating layer, a diameter of the via decreases in a direction from the second insulating layer toward the first insulating layer, and gradually decreases at a greater ratio as getting closer toward the first insulating layer from the second insulating layer.

9. The wiring structure of claim 1, wherein:
the third via pad is integrated with the via.

10. The wiring structure of claim 1, wherein:
in each of areas penetrating the first insulating layer and the second insulating layer, the via is in contact with the first insulating layer or the second insulating layer.

11. A semiconductor package comprising:
a first redistribution structure;
a support substrate on the first redistribution structure, the support substrate comprising a first wiring layer including a first via pad and a first insulating layer the support substrate defining a through hole;
a semiconductor chip in the through hole;
an encapsulant filling the through hole and covering the semiconductor chip and the support substrate; and
a second redistribution structure on the encapsulant,
wherein the second redistribution structure comprises,
a first redistribution layer on the encapsulant and comprising a second via pad defining a hole,
a second insulating layer on the encapsulant and covering the first redistribution layer,
a second redistribution layer on the second insulating layer and comprising a third via pad, and
a via integrally penetrating the encapsulant and the second insulating layer, filling the hole of the second via pad, and connecting the first via pad, the second via pad, and the third via pad to each other, the first insulating layer covers upper and side surfaces of the first via pad, and
a diameter of the first via pad is smaller than a diameter of the second via pad and a diameter of the third via pad.

12. The semiconductor package of claim 11, wherein:
the diameter of the first via pad ranges from 65 μm to 75 μm.

13. The semiconductor package of claim 11, wherein:
an average diameter of the via in an area penetrating the encapsulant is smaller than an average diameter of the via in an area penetrating the second insulating layer.

14. The semiconductor package of claim 11, wherein:
a diameter of the via ranges from 40 μm to 50 μm at the upper surface of the first via pad.

15. The semiconductor package of claim 11, wherein:
a diameter of the via ranges from 45 μm to 55 μm in an area filling the hole of the second via pad.

16. The semiconductor package of claim 11, wherein:
a diameter of the via is constant in an area filling the hole of the second via pad.

17. The semiconductor package of claim 11, wherein:
when a surface of the via in contact with the upper surface of the first via pad is referred to as a first bottom surface, and a surface of the via in contact with an upper surface of the second via pad is referred to as a second bottom surface,
a distance between a center of the via and a center of the first via pad at the first bottom surface is closer than a distance between the center of the via and a center of the second via pad at the second bottom surface, when viewed in a top view.

18. A method of manufacturing a wiring structure, the method comprising:
forming a first wiring layer comprising a first via pad;
forming a first insulating layer covering the first wiring layer;
forming a second wiring layer on the first insulating layer, the second wiring layer comprising a second via pad, the second via pad defining a hole;
forming a second insulating layer covering the second wiring layer on the first insulating layer;
forming a via hole integrally penetrating the first insulating layer and the second insulating layer to expose an upper surface of the first via pad, an inner surface of the second via pad surrounding the hole, and an upper surface adjacent to the inner surface of the second via pad;
forming a via filling the via hole; and
forming a third wiring layer comprising a third via pad connected to the via on the second insulating layer.

19. The method of claim 18, wherein:
the forming of the via hole is performed through laser processing.

20. The method of claim 18, wherein:
in the forming of the via, the via is formed to be in contact with each of the first insulating layer, the second insulating layer, the first via pad, and the second via pad.
